(19) United States
(12) Patent Application Publication
(10) Pub. No.: US 2009/0009964 A1
(43) Pub. Date: Jan. 8, 2009

(54) Heatsink and Cooling Apparatus

(76) Inventor: Mitsuru Suzuki, Yokohama-shi (JP)

Correspondence Address: BARLEY SNYDER, LLC, 1000 WESTLAKES DRIVE, SUITE 275, BERWYN, PA, 19312, US

(21) Appl. No.: 12/167,471

(22) Filed: Jul. 3, 2008

(30) Foreign Application Priority Data
Jul. 6, 2007 (JP) 2007-178776

(51) Int. Cl. H05K 7/20

(52) U.S. Cl. 361/692

(57) ABSTRACT

A heatsink and a cooling apparatus for cooling a heating element wherein the heatsink includes a rolled metal plate having a central axis at a central portion thereof. The metal plate has a first end and a second end. The second end is arranged closer to the central axis than the first end. The metal plate has a height in a direction of the central axis that gradually increases from the first end toward the second end in a radial direction.

### CROSS-REFERENCE TO RELATED APPLICATIONS

The application claims the benefit of the filing date under 35 U.S.C. §119(a)-(d) of Japan Patent Application No. 2007-178776, filed Jul. 6, 2007.

### FIELD OF THE INVENTION

The present invention relates to a heatsink and a cooling apparatus for cooling a heating element, such as a light emitting diode (LED), wherein the heatsink includes a rolled metal plate.

### BACKGROUND

Forced convection-type cooling apparatuses having a relatively large cooling capacity have widely been used in the past as cooling apparatuses for cooling heating elements. The term “forced convection-type cooling apparatuses” refers to cooling apparatuses having a construction in which a fan is added to a heatsink. An example of such a forced convection-type cooling apparatus is shown in FIG. 10 (JP 2004-063563A). FIG. 10 shows a cooling apparatus 101 including a heatsink 110 and a fan 120. The heatsink 110 is constructed from a radiating fin 112 formed by rolling a band-form metal plate in a spiral shape in a direction of arrow R. A radiating plate 111 is provided on one end (toward the bottom in FIG. 10) in the direction of a central axis CL of the rolled radiating fin 112. A heating element (not shown) is designed to be attached to a surface of the radiating plate 111 on a side opposite from the radiating fin 112.

A plurality of substantially rectangular apertures 113 that pass through in a direction of thickness of the radiating fin 112 are formed in the radiating fin 112. Each of the apertures 113 is formed by cutting a portion of the radiating fin 112 and raising the portion inward (toward the central axis CL). Tongues 114 that are created when the portions of the radiating fin 112 are cut and raised to form the apertures 113 are inclined toward the central axis CL so as to conform to the flow of air passing through the apertures 113 from the inside toward the outside.

The fan 120 is an axial flow fan that is mounted in a detachable manner on the other end (toward the top in FIG. 10) of the radiating fin 112. The direction of rotation of the fan 120 is the same as the direction of the arrow R, which is the direction of rolling of the radiating fin 112. Cool air from the fan 120 is therefore blown into the radiating fin 112.

In the cooling apparatus 101 constructed in this manner, the radiating fin 112 has a shape that is obtained by rolling a band-form material in a scroll-like manner, so that it is possible to easily change the pitch dimension between the plates in the radial direction and to increase the heat dissipation area without increasing the overall size of the heating element cooling apparatus 101. Because the direction of rolling of the radiating fin 112 and the direction of rotation of the fan 120 coincide, the direction of swirling of cool air that is blown into the fan 120 and the direction of rolling of the radiating fin 112 can be caused to coincide, so that the cool air can be caused to flow smoothly into the radiating fin 112.

Because the plurality of the apertures 113 that pass through in the direction of thickness of the radiating fin 112 are formed in the radiating fin 112, it is possible to expect the effect of increasing the heat transfer coefficient at corner edges of the tongues 114 and the effect of suppressing the growth of a thermal boundary layer by disturbing the flow of the cool air passing through the apertures 113. The tongues 114 are inclined toward the central axis CL along the flow of the air passing through the apertures 113. Therefore, the air passing through the apertures 113 from the inside toward the outside can be flown smoothly into the radiating fin 112.

Incidentally, LED lighting devices have recently appeared as the technical field that requires cooling apparatuses for cooling heating elements. In the LED lighting devices, there is demand for higher-power LEDs to obtain high brightness (e.g., demand to allow an increase in the power consumption from the conventional approximately 4 W to approximately 8 W to 15 W). However, natural convection-type cooling apparatuses (cooling apparatuses based solely on heat dissipation by a heatsink without providing a fan), which tend to have insufficient cooling capacity, have been used in the past to cool the LED lighting devices, so that the production of higher-power LEDs finds itself in a difficult situation.

In cooling the LED lighting devices, it is also conceivable to use forced convection-type cooling apparatuses, such as the cooling apparatus 101 shown in FIG. 10. However, because a fan is used in forced convection-type cooling apparatuses, such as the cooling apparatus 101 shown in FIG. 10, noise or the like becomes an issue. Thus, it is unrealistic to use such a forced convection-type cooling apparatus in the cooling of the LED lighting devices.

### SUMMARY

It is therefore an object of the present invention to provide a natural convection-type heatsink and cooling apparatus for cooling a heating element which are suitable for LED lighting devices or the like and which have increased cooling capacity.

This and other objects are achieved by a heatsink for cooling a heating element comprising a rolled metal plate having a central axis at a central portion thereof. The metal plate has a first end and a second end. The second end is arranged closer to the central axis than the first end. The metal plate has a height in a direction of the central axis that gradually increases from the first end toward the second end in a radial direction.

This and further objects are achieved by a cooling apparatus comprising a printed wiring board, a heating element provided on an undersurface of the printed wiring board, and a heatsink provided on an upper surface of the printed wiring board substantially above the heating element. The heatsink includes a rolled metal plate having a central axis at a central portion thereof. The metal plate has a first end and a second end. The second end is arranged closer to the central axis than the first end. The metal plate has a height in a direction of the central axis that gradually increases from the first end toward the second end in a radial direction.

### BRIEF DESCRIPTION OF THE DRAWINGS

FIG. 1 is a schematic partial sectional view of a heatsink according to a first embodiment of the present invention mounted in a lighting device;

FIG. 2A is a plan view of the heatsink of FIG. 1;

FIG. 2B is a partial cut away front view of the heatsink of FIG. 1;

FIG. 2C is an enlarged view of portion 2C of FIG. 2A;

FIG. 3 is a plan view of an unrolled metal plate constituting the heatsink of FIG. 2A;

FIG. 4 is a sectional view along line 4-4 of FIG. 3;

FIG. 5A is a plan view of a heatsink according to a second embodiment of the present invention;

FIG. 5B is a partial cut away front view of the heatsink of FIG. 5A;

FIG. 5C is an enlarged view of portion 5C of FIG. 5A;

FIG. 6 is a plan view of an unrolled metal plate constituting the heatsink of FIG. 5A;

FIG. 7 is a sectional view along line 7-7 of FIG. 6;

FIG. 8A is a plan view of a heatsink according to a third embodiment of the present invention;

FIG. 8B is a partial cut away front view of the heatsink of FIG. 8A;

FIG. 8C is an enlarged view of portion 8C of FIG. 8A;

FIG. 9 is a plan view of an unrolled metal plate constituting the heatsink of FIG. 8; and

FIG. 10 is a partially exploded schematic perspective view of a conventional cooling apparatus according to the prior art.

### DETAILED DESCRIPTION OF THE EMBODIMENT(S)

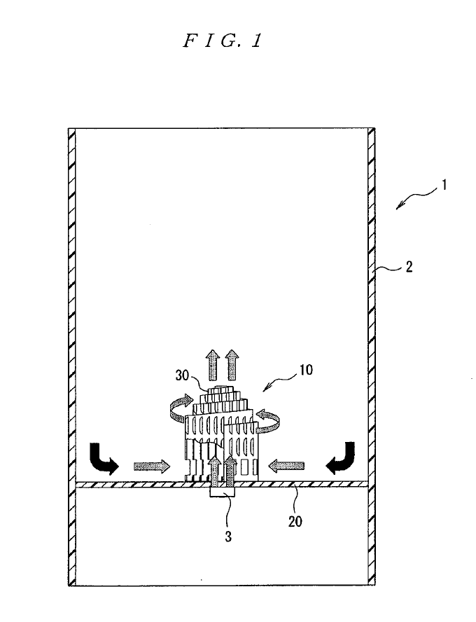

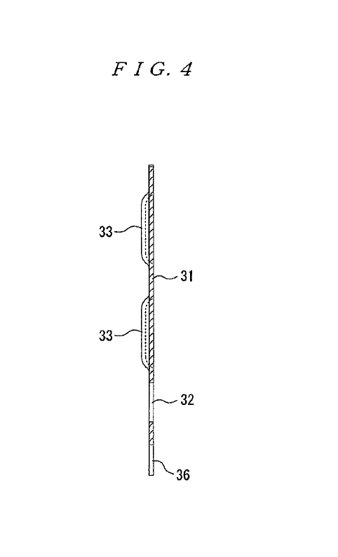

Embodiments of the present invention will be described below with reference to the figures. FIGS. 1-4 show a heatsink 30 according to a first embodiment of the invention. As shown in FIG. 1, a printed wiring board 20 is installed inside a housing 2 of a lighting device 1. A heating element 3 is mounted on an undersurface of the printed wiring board 20. The heating element 3 may be, for example, a LED. The heatsink 30 that is provided for cooling the heating element 3 is mounted on an upper surface of the printed wiring board 20. The printed wiring board 20 is a double-sided board having Cu layers respectively formed on the upper surface and undersurface thereof. The heatsink 30 is brazed (soldered) by reflow to the Cu layer on the upper surface. The heatsink 30 is designed to be mounted on the upper surface of the printed wiring board 20 in a vertical direction in relation to the heating element 3 in a position in which the heating element 3 is located in a central portion in a radial direction. The heatsink 30 and the printed wiring board 20 thereby constitute a cooling apparatus 10.

The housing 2 of the lighting device 1 is shown as having a cylindrical shape, but may be formed in other shapes. The housing 2 is made, for example, of a resin material. The housing 2 is made of resin material instead of a metal material, such as aluminum, because the resin material affords a higher degree of freedom in design and a lower cost. It should be noted, however, that the housing 2 made of the resin material has a disadvantage compared to a housing made of metal from the standpoint of dissipating heat generated by the heating element 3. For this reason, there is demand to further increase the heat dissipation effect with the heatsink 30 and the cooling apparatus 10.

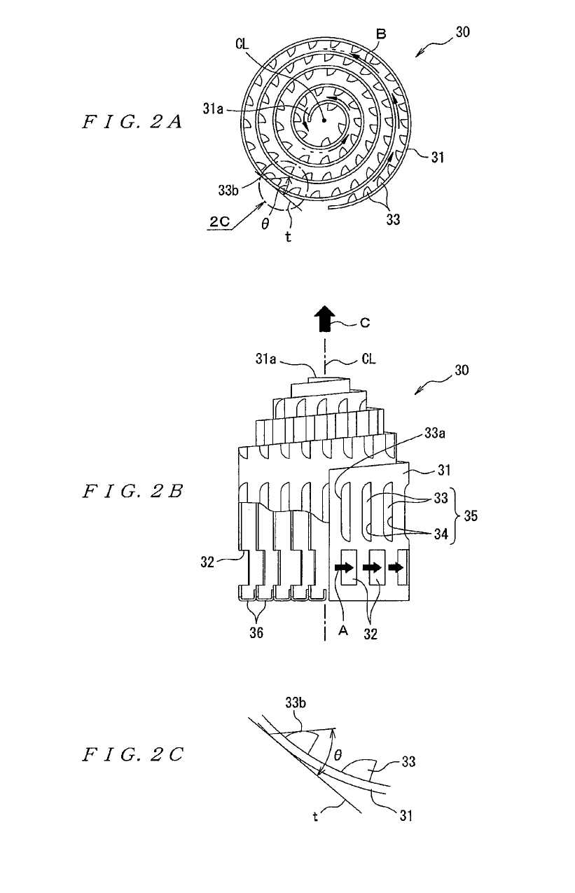

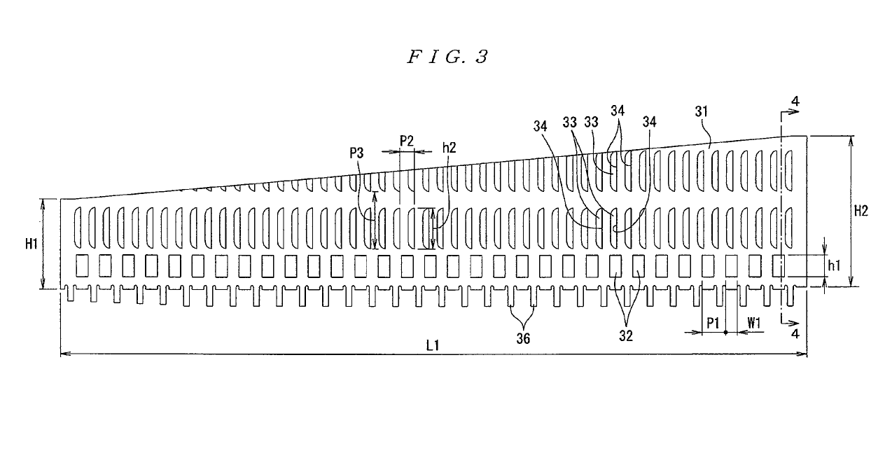

As shown in FIGS. 2A-2B, the heatsink 30 is formed by rolling a band-form metal plate 31 in the shape of a scroll with a central axis CL as a center. The heatsink 30 can be mass-produced by successively working a single long band-form metal plate 31. The central axis CL is a virtual axis. The direction of rolling of the metal plate 31 is clockwise, as shown in FIG. 2A, but may also be reversed to be counterclockwise. A metal material, such as aluminum, may be used, for example, to form the metal plate 31. As shown in FIG. 3, the metal plate 31 that is in the unrolled state has a trapezoidal shape in which the height is gradually increased from one end edge toward the other end edge in a direction of length (left-right direction in FIG. 3), with the height at the first end in the direction of length being designated as H1, and the height at the second end in the direction of length being designated as H2, which is higher than H1. The lower end edge (lower end edge in FIG. 3) of the metal plate 31 extends so as to be orthogonal to both the first end and second end in the direction of length, while the upper end edge of the metal plate 31 extends at an inclination from the first end to the second end in the direction of length. When the metal plate 31 is rolled (like a scroll) such that the second end having the height H2 is on the inside, the height on one side (upper side) in the direction of the central axis CL is gradually increased from the outside in the radial direction toward the central portion 31a in the radial direction, as shown in FIGS. 2A-2B.

A plurality of air intake openings 32 that pass through in the direction of thickness of the metal plate 31 are formed toward the lower end in the direction of the central axis CL of the heatsink 30, as shown in FIG. 2B. As shown in FIG. 3, each of the air intake openings 32 is formed in a rectangular shape with a width of w1 and a height (length in the vertical direction) of h1. The air intake openings 32 are arranged at a pitch of P1 along the direction of length of the metal plate 31. By forming the air intake openings 32, the surface area of the heatsink 30 is increased, so that the heat dissipation effect is increased. The air intake openings 32 have the function of taking in air from the outside of the heatsink 30 to the inside, but in addition to that, the air intake openings 32 also function as pilot apertures when the metal plate 31 is rolled and when louver-form openings 35 (described later) are stamped and formed. If the air intake openings 32 are not formed, it is necessary to provide a portion for forming pilot apertures on the outside of the metal plate 31 and to cut off the portion in which the pilot apertures are formed after the completion of the heatsink 30. However, as a result of the air intake openings 32 functioning as such pilot apertures, there is no need to form separate pilot apertures on the outside of the metal plate 31 in that manner, so that material can be saved.

The louver-form openings 35 are formed in the heatsink 30, as shown in FIG. 2B. Each of the louver-form openings 35 comprises a circular arc-shaped fin 33 formed by stamping and forming the metal plate 31 inwardly in the radial direction, and a slit-form opening (hereafter simply referred to as a slit) 34 produced as a result of forming the fin 33. Each of the fins 33 is cut and raised from the metal plate 31 such that a line 33a connecting both cut-and-raised end parts extends parallel to the direction of the central axis CL of the heatsink 30, i.e., in the direction of extension of the louver, as shown in FIG. 2B. Each of the fins 33 is cut and raised from the heatsink 30 such that a plane 33b of each of the fins 33 extends parallel to the direction of the central axis CL, i.e., in the vertical direction, and also such that an angle θ formed by the plane 33b of each of the fins 33 and a tangential line t of the heatsink 30 (metal plate 31) is an acute angle, as shown in FIG. 2C. The slits 34 are positioned above the air intake openings 32 and arranged in two rows, i.e., an upper row and a lower row, as shown in FIG. 3. Each of the slits 34 is formed with a height (length in the vertical direction) h2. The slits 34 in each row are arranged at a pitch P2 along the direction of length of the metal plate 31. The slits 34 in the upper row and the slits 34 in the lower row are arranged at a pitch P3. Thus, by forming the louver-form openings 35 in the heatsink 30, the surface area of the heatsink 30 is increased, so that the heat dissipation effect is increased.

Legs 36 are provided on the lower end edge of the heatsink 30 at a specified pitch along the direction of length. The legs 36 are bent after the metal plate 31 is rolled into the shape of a scroll with the central axis CL as the center such that the legs 36 on the outside in the radial direction respectively contact the metal plate 31 on the inside in the radial direction, as shown in FIG. 2B. The undersurfaces of the legs 36 are brazed (soldered) by reflow to the Cu layer formed on the upper surface of the printed wiring board 20, thus mounting the heatsink 30 on the printed wiring board 20. The heatsink 30 is mounted on the upper surface of the printed wiring board 20 in the vertical direction in relation to the heating element 3 in a position in which the heating element 3 is located in the center of the heatsink 30 in the radial direction.

In the lighting device 1 constructed in the manner, when the heating element 3 generates heat, the heat is transferred to the heatsink 30 and the air inside the heatsink 30 via the printed wiring board 20. As a result, the temperatures of the heatsink 30 and the air inside the heatsink 30 rise. The temperatures of the heatsink 30 and the air inside the heatsink 30 are the highest at the center in the radial direction where the heating element 3 is located, and become gradually lower toward the outside in the radial direction. The temperatures are higher in the lower portion of the heatsink 30, and lower in the upper portion of the heatsink 30. When the heatsink 30 is viewed as a whole, because there is a temperature difference between the lower portion and upper portion of the heatsink 30, an updraft is generated by the chimney effect.

The heatsink 30 is formed by rolling the metal plate 31 in the shape of a scroll with the central axis CL as the center and is constructed such that the height on one side (upper side) in the direction of the central axis CL is gradually increased from the outside in the radial direction toward a central portion 31a in the radial direction, so that a temperature difference in the direction of the central axis CL can be created easily at the central portion 31a of the heatsink 30 in the radial direction. The heatsink 30 is mounted, with the side of the other end (side of the lower end) in the direction of the central axis CL being at the bottom, on the upper side of the heating element 3 in the vertical direction and in a position in which the heating element 3 is located in the center in the radial direction. Therefore, with regard to the temperatures of the heatsink 30 and the air inside the heatsink 30, the temperatures in the center in the radial direction of the heatsink 30 can be made to be higher than toward the outside in the radial direction, and the temperature difference in the direction of the central axis CL can be made to be greater in the center in the radial direction. Accordingly, the chimney effect at the center of the heatsink 30 in the radial direction is made to be greater than the chimney effect toward the outside in the radial direction, so that the flow velocity of the updraft in the direction of arrow C shown in FIG. 2B can be increased at the center of the heatsink 30, thus making it possible to create a pressure gradient in which the pressure is gradually lowered from the outside toward the center in the radial direction.

The plurality of air intake openings 32 that pass through in the direction of thickness of the metal plate 31 are formed on the side of the second end (on the side of the lower end) in the direction of the central axis CL, so that air can be taken in from the outside of the heatsink 30 in a direction of arrows A shown in FIG. 2B via the air intake openings 32. Then, air flow from the outside of the heatsink 30 toward the center in the radial direction in a direction of arrows B shown in FIG. 2A is generated due to the pressure difference described above (which is such that the pressure is gradually lowered from the outside toward the center in the radial direction), so that spiral-form air flow is generated in the heatsink 30 as a whole. As a result, the air taken in from the outside of the heatsink 30 via the air intake openings 32 undergoes convection toward the center in the radial direction. The air convection causes the air that is warmed up inside the heatsink 30 to be expelled by air that is not warmed up much, so that it is possible to produce a natural convection-type heatsink 30 for cooling the heating element 3 with increased cooling capacity.

The fins 33 that are cut and raised inward in the radial direction are formed in the heatsink 30. Consequently, the heat radiated from the fins 33 is directed inward in the radial direction, so that the temperatures of the heatsink 30 and the air inside the heatsink 30 become gradually higher from the outside in the radial direction toward the inside in the radial direction, and become highest at the center in the radial direction. Therefore, the fins 33 can cause the air to act in a direction that maintains the condition of making the temperatures the highest at the center in the radial direction.

Each of the fins 33 is cut and raised from the heatsink 30 such that the line 33a connecting both cut-and-raised end parts extends parallel to the direction of the central axis CL of the heatsink 30 and such that the angle θ formed by the plane 33b of each of the fins 33 and the tangential line t of the metal plate 31 is an acute angle. Therefore, the planes 33b of the respective fins 33 guide the air undergoing convection inside the heatsink 30 toward the center of the heatsink 30 in the radial direction, thus making it possible to cause the air to act in a direction which is such that a reduction in the flow velocity of the air is as little as possible.

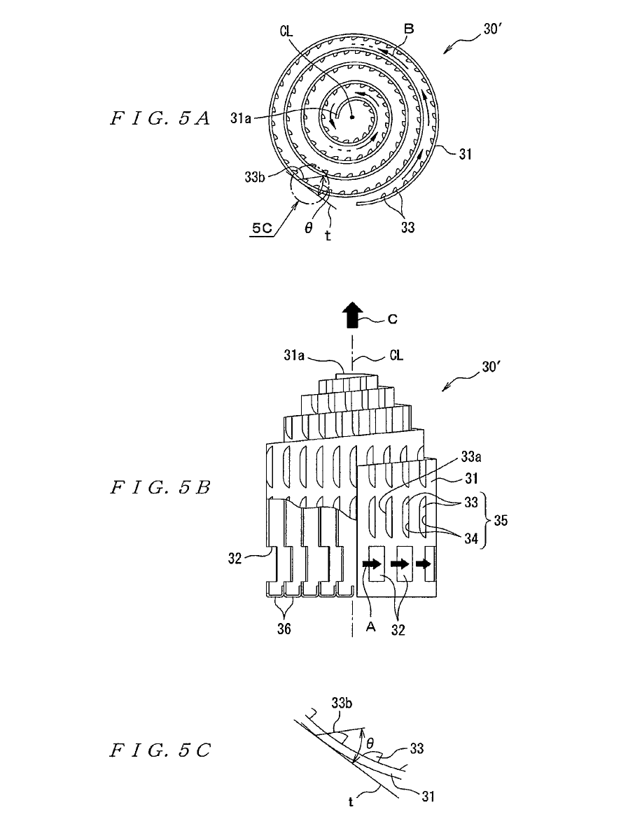

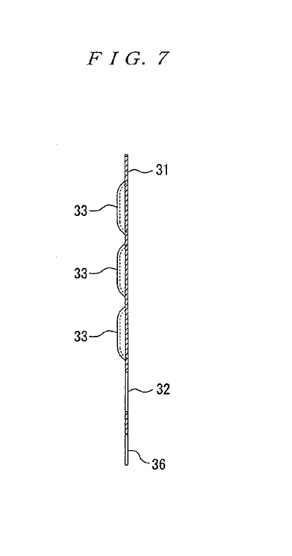

FIGS. 5A-7 show a heatsink 30′ according to a second embodiment of the invention. The elements of the heatsink 30′ that are identical to the elements of the heatsink 30 shown in FIGS. 1-4 will be illustrated with the same reference numerals and further description thereof will be omitted hereafter.

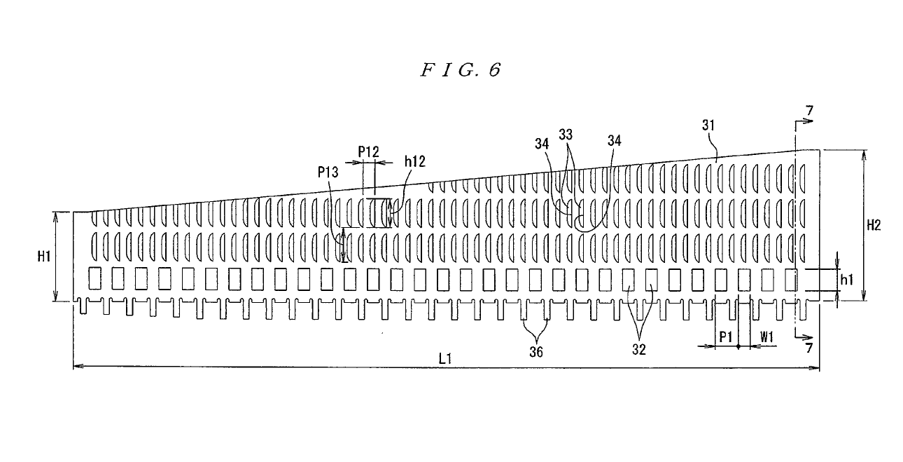

As shown in FIGS. 5A-5C, the heatsink 30′ is different from the heatsink 30 in that the slits 34 of the louver-form openings 35 are positioned above the air intake openings 32 and are arranged in three rows in the vertical direction, as shown in FIG. 6. Each of the slits 34 is formed with a height (length in the vertical direction) h12, which is smaller than the height h2 in the heatsink 30. The slits 34 in each row are arranged along the direction of length of the metal plate 31 at an arrangement pitch of P12, which is smaller than the arrangement pitch P2 of the slits 34 of the heatsink 30. The slits 34 in an upper row, the slits 34 in a middle row, and the slits 34 in a lower row are arranged at a pitch of P13 which is smaller than the pitch P3. In the heatsink 30′, it is preferable to appropriately select the manner of the arrangement of the louver-form openings 35 either as shown in FIGS. 5A-7 or as shown in FIGS. 2A-4 according to the magnitude of the power consumption of the heating element 3.

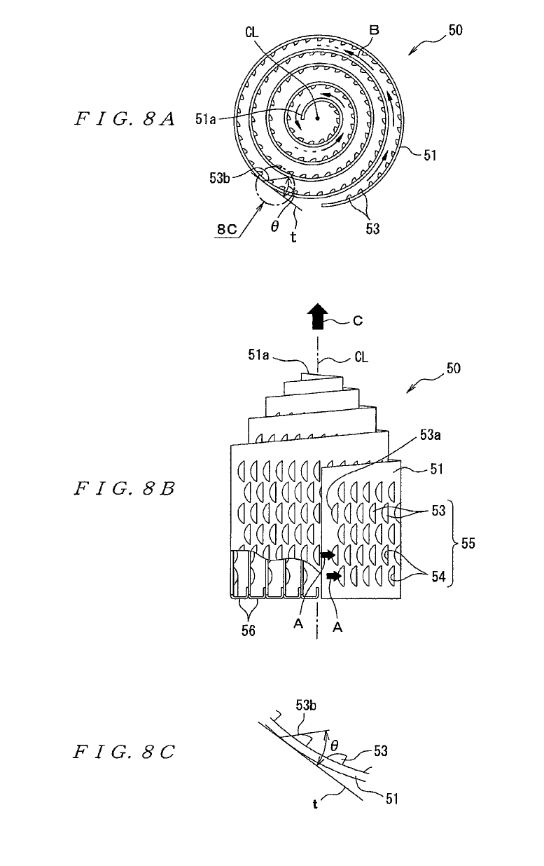

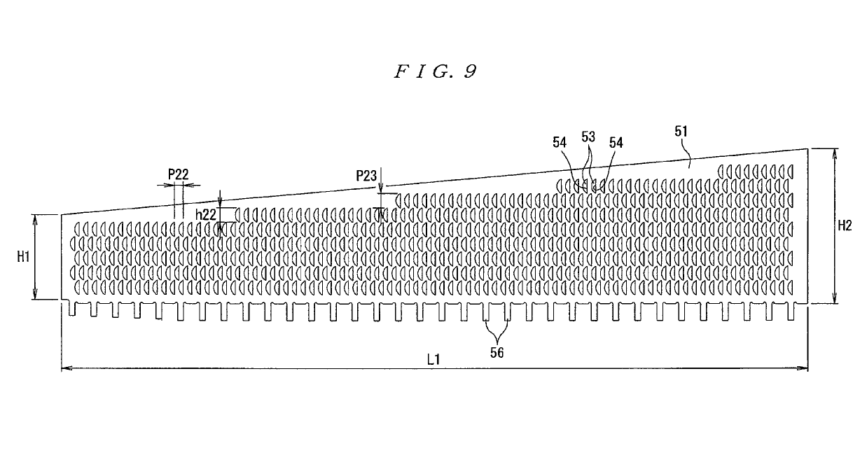

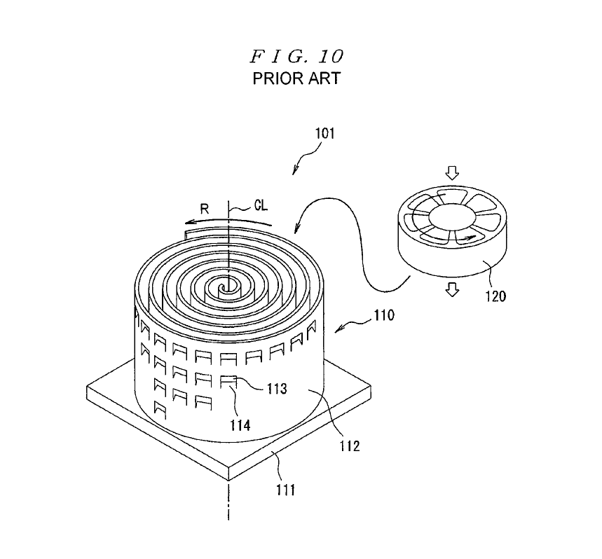

FIGS. 8A-9 show a heatsink 50 according to a third embodiment of the invention. The heatsink 50 shown in FIGS. 8A-9 can be used in the lighting device 1 shown in FIG. 1 and is formed by rolling a band-form metal plate 51 in the shape of a scroll with a central axis CL as the center, as shown in FIGS. 8A-8B. The direction of rolling of the metal plate 51 is clockwise as seen in plan view in FIG. 8A, but may also be counterclockwise. As shown in FIG. 9, the metal plate 51 that is in the unrolled state has a trapezoidal shape, with the height at one end edge in the direction of length (left-right direction in FIG. 9) being designated as H1, and the height at the other end edge in the direction of length being designated as H2, which is higher than H1. The lower end edge (lower end edge in FIG. 9) of the metal plate 51 extends so as to be orthogonal to both the first end and second end in the direction of length, while the upper end edge of the metal plate 51 extends at an inclination from the first end to the second end in the direction of length. Therefore, when the metal plate 51 is rolled (like a scroll) such that the second end having the height H2 is on the inside, the height on one side (upper side) in the direction of the central axis CL is gradually increased from the outside in the radial direction toward a central portion 51a in the radial direction.

A plurality of louver-form openings 55 are formed in the heatsink 50, as shown in FIGS. 8A-8B. Each of the openings 55 comprises a circular arc-shaped fin 53 that is cut and raised by stamping and forming the metal plate 51 inward in the radial direction and a slit-form opening (hereafter simply referred to as slit) 54 produced as a result of forming the fin 53. The manner in which the fins 53 are cut and raised is the same as in the fins 33 of the heatsink 30 shown in FIGS. 2A-2B, and each of the fins 53 is cut and raised from the metal plate 51 such that a line 53a connecting both raised end parts extends parallel to the direction of the central axis CL of the heatsink 50, i.e., in the direction of extension of the louver. Each of the fins 53 is cut and raised from the heatsink 50 such that the plane 53b of each of the fins 53 extends parallel to the direction of the central axis, i.e., in the vertical direction, and also such that the angle θ formed by the plane 53b of each of the fins 53 and the tangential line t of the scroll-form heatsink 50 (metal plate 51) is an acute angle, as shown in FIG. 8A.

The slits 54 are arranged in nine rows in the vertical direction, as shown in FIG. 9. The slits 54 are arranged in a zigzag fashion along the vertical direction from the slits 54 in the uppermost row to the slits 54 in the lowermost row. The slits 54 are arranged along the vertical direction at a pitch of P23 from the slits 54 in an uppermost-row to the slits 54 in a lowermost-row. Each of the slits 54 is formed with a height (length in the vertical direction) h22. The slits 54 in each row are arranged at a pitch of P22 along the direction of length of the metal plate 51. The height h22 of each of the slits 54 is smaller than the height h2 of the slits 34 in the heatsink 30 shown in FIG. 2.

A plurality of legs 56 are provided on the lower end edge of the heatsink 50 metal plate 51 at a specified pitch along the direction of length. The legs 56 are bent after the metal plate 51 is rolled into the shape of a scroll with the central axis CL as the center such that the legs 56 on the outside in the radial direction respectively touch the metal plate 51 on the inside in the radial direction as shown in FIG. 8B.

As in the heatsink 30 shown in FIG. 1, the undersurfaces of the legs 56 are brazed (soldered) by reflow to the Cu layer formed on the upper surface of the printed wiring board 20, thus mounting the heatsink 50 on the printed wiring board 20. In the case, the heatsink 50 is mounted on the upper surface of the printed wiring board 20 in the vertical direction in relation to the heating element 3 in a position in which the heating element 3 is located in the center in the radial direction.

In the heatsink 50 shown in FIGS. 8A-9, there are no openings having the same shape as the air intake openings 32 that are formed in the heatsink 30 shown in FIGS. 2A-4. In the heatsink 50 shown in FIGS. 8A-9, the openings 55 that are formed toward the lower end of the heatsink 50 in the direction of the central axis CL in approximately two rows from the bottom have the same function as the air intake openings 32. Accordingly, air is taken into the interior of the heatsink 50 as indicated by arrow A from the outside of the heatsink 50 through the openings 55 in approximately two rows from the bottom, as shown in FIG. 8B.

It is preferable to select appropriately whether to use the heatsink 50 shown in FIGS. 8A-9 or whether to use the heatsink 30, 30′ shown in FIGS. 2A-7 according to the magnitude of the power consumption of the heating element 3. By using the heatsink 50 shown in FIGS. 8A-9, the surface area of the heatsink 50 can be made to be different from the surface area of the heatsink 30, 30′.

The foregoing illustrates some of the possibilities for practicing the invention. Many other embodiments are possible within the scope and spirit of the invention. For example, the legs 36, 6 of the heatsink 30, 30′, 50 are brazed (soldered) to the printed wiring board 20. However, it would also be possible to interpose an aluminum plate (not shown) as a heat transfer member between the printed wiring board 20 and the heatsink 30, 30′, 50. The size, number, and arrangement of the fins 33, 53 and slits 34, 54 that respectively constitute the openings 35, 55 and the air intake openings 32 may be determined appropriately according to the magnitude of the power consumption of the heating element 3. Further, the lighting device 1 that uses an LED as the heating element 3 was described as an example in the present embodiment. However, the heatsinks 30, 30′, 50 and the cooling apparatus 10 can be applied to any device that is used to cool an electronic component other than an LED or another heating element. It is, therefore, intended that the foregoing description be regarded as illustrative rather than limiting, and that the scope of the invention is given by the appended claims together with their full range of equivalents.

What is claimed is:

1. A heatsink for cooling a heating element, comprising:
a rolled metal plate having a central axis at a central portion thereof, the metal plate having a first end and a second end, the second end being arranged closer to the central axis than the first end, the metal plate having a height in a direction of the central axis that gradually increases from the first end toward the second end in a radial direction.

2. The heatsink of claim 1, wherein the metal plate has an upper surface and a lower surface, the upper surface extending at an inclination from the first end to the second end and the lower surface extending orthogonal to the first end and the second end.

3. The heatsink of claim 1, wherein the metal plate is provided with a plurality of air intake openings that pass through the metal plate in a direction of thickness of the metal plate.

4. The heatsink of claim 3, wherein the air intake openings have a rectangular shape.

5. The heatsink of claim 1, wherein the metal plate is provided with a plurality of circular arc-shaped fins that extend inward in the radial direction.

6. The heatsink of claim 5, wherein adjacent to each of the fins the metal plate is provided with slits extending in the direction of the central axis.

7. The heatsink of claim 6, wherein the slits are arranged in at least two rows extending in a direction of length of the metal plate, the slits in each of the rows being offset from each other.

8. The heatsink of claim 5, wherein a plane of each of the fins extends parallel to the direction of the central axis.

9. The heatsink of claim 8, wherein an angle formed by the plane of each of the fins and a tangential line of the metal plate is an acute angle.

10. The heatsink of claim 1, wherein the metal plate includes a plurality of legs extending there from, each of the legs extending toward the central axis and contacting a portion of the metal plate arranged closer to the central axis than a portion of the metal plate from which the leg extends.

11. A cooling apparatus, comprising:
a printed wiring board;
a heating element provided on an undersurface of the printed wiring board; and
a heatsink provided on an upper surface of the printed wiring board substantially above the heating element, the heatsink including a rolled metal plate having a central axis at a central portion thereof, the metal plate having a first end and a second end, the second end being arranged closer to the central axis than the first end, the metal plate having a height in a direction of the central axis that gradually increases from the first end toward the second end in a radial direction.

12. The cooling apparatus of claim 11, wherein the metal plate has an upper surface and a lower surface, the upper surface extending at an inclination from the first end to the second end and the lower surface extending orthogonal to the first end and the second end.

13. The cooling apparatus of claim 11, wherein the metal plate is provided with a plurality of air intake openings that pass through the metal plate in a direction of thickness of the metal plate.

14. The cooling apparatus of claim 13, wherein the air intake openings have a rectangular shape.

15. The cooling apparatus of claim 11, wherein the metal plate is provided with a plurality of circular arc-shaped fins that extend inward in the radial direction.

16. The cooling apparatus of claim 15, wherein adjacent to each of the fins the metal plate is provided with slits extending in the direction of the central axis.

17. The cooling apparatus of claim 16, wherein the slits are arranged in at least two rows extending in a direction of length of the metal plate, the slits in each of the rows being offset from each other.

18. The cooling apparatus of claim 15, wherein a plane of each of the fins extends parallel to the direction of the central axis.

19. The cooling apparatus of claim 18, wherein an angle formed by the plane of each of the fins and a tangential line of the metal plate is an acute angle.

20. The cooling apparatus of claim 11, wherein the metal plate includes a plurality of legs extending there from, each of the legs extending toward the central axis and contacting a portion of the metal plate arranged closer to the central axis than a portion of the metal plate from which the leg extends.
